(19) United States
(12) Patent Application Publication
(10) Pub. No.: US 2020/0227402 A1
(43) Pub. Date: Jul. 16, 2020

(54) ZENER DIODES AND METHODS OF MANUFACTURE

(71) Applicant: SEMICONDUCTOR COMPONENTS INDUSTRIES, LLC, Phoenix, AZ (US)

(72) Inventors: Gourab SABUI, Santa Clara, CA (US); Yupeng CHEN, San Jose, CA (US); Umesh SHARMA, San Jose, CA (US)

(73) Assignee: SEMICONDUCTOR COMPONENTS INDUSTRIES, LLC, Phoenix, AZ (US)

(21) Appl. No.: 16/249,553

(22) Filed: Jan. 16, 2019

(51) Int. Cl. H01L 27/02; H01L 29/866; H01L 29/66; H01L 29/36; H01L 29/06

(52) U.S. Cl. CPC H01L 27/0255; H01L 29/866; H01L 29/0615; H01L 29/36; H01L 29/66106

(57) ABSTRACT

In a general aspect, a semiconductor device can include a heavily-doped substrate of a first conductivity type, a lightly-doped epitaxial layer of a second conductivity type disposed on the heavily-doped substrate, and a heavily-doped epitaxial layer of the second conductivity type disposed on the lightly-doped epitaxial layer. The heavily-doped epitaxial layer can have a doping concentration that is greater than a doping concentration of the lightly-doped epitaxial layer. At least a portion of the heavily-doped substrate can be included in a first terminal of a Zener diode, and at least a portion of the lightly-doped epitaxial layer and at least a portion of the heavily-doped epitaxial layer can be included in a second terminal of the Zener diode. The semiconductor device can further include a termination trench that extends through the heavily-doped epitaxial layer and the lightly-doped epitaxial layer, and terminates in the heavily-doped substrate.

### TECHNICAL FIELD

This description relates to electrical surge protection devices. More specifically, this description relates to Zener diodes and associated methods of manufacture.

### BACKGROUND

Electrical circuits, during operation, can experience undesirable electrical surges, (e.g., voltage and/or current surges), which can also be referred to as transients (e.g., voltage and/or current transients). Such electrical surges (surges or transients) can cause damage to elements of an electrical circuit, such as to an integrated circuit (IC), transistors devices, or other circuit elements. Such damage can be irreversible and can, as a result, cause an associated electrical circuit to fail (e.g., not perform, or function as intended). In order to prevent such damage, protection devices (electrical protection devices) can be included in an electrical circuit to protect elements of the circuit that are susceptible to damage from electrical surges.

Zener diodes are one type of protection device that can be included in an electrical circuit to provide protection, from electrical surges, to other elements of the electrical circuit. For instance, Zener diodes can be implemented in an electrical circuit (e.g., connected between signal terminal on which a susceptible circuit element can receive and electrical surge and electrical ground) to absorb (conduct to electrical ground, divert to electrical ground, etc.) electrical energy associated with an electrical surge, so as to protect susceptible circuit elements from damage that could be cause (result from) the absorbed energy. Current Zener diode implementations do not, however, provide adequate protection from electrical surges in some implementations. For example, current Zener diode implementations may not have sufficient surge current carrying capability and/or low enough clamping voltages to provide electrical surge protection in some implementations.

### SUMMARY

In a general aspect, a semiconductor device can include a heavily-doped substrate of a first conductivity type; a lightly-doped epitaxial layer of a second conductivity type disposed on the heavily-doped substrate, the second conductivity type being opposite the first conductivity type; and a heavily-doped epitaxial layer of the second conductivity type disposed on the lightly-doped epitaxial layer. The heavily-doped epitaxial layer can have a doping concentration that is greater than a doping concentration of the lightly-doped epitaxial layer. At least a portion of the heavily-doped substrate can be included in a first terminal of a Zener diode. At least a portion of the lightly-doped epitaxial layer and at least a portion of the heavily-doped epitaxial layer can be included in a second terminal of the Zener diode. The semiconductor device can further include a termination trench that extends through the heavily-doped epitaxial layer; extends through the lightly-doped epitaxial layer; and terminates in the heavily-doped substrate.

In another general aspect, a semiconductor device can include a heavily-doped substrate of a first conductivity type; a lightly-doped epitaxial layer of a second conductivity type disposed on the heavily-doped substrate, the second conductivity type being opposite the first conductivity type; and a heavily-doped epitaxial layer of the second conductivity type disposed on the lightly-doped epitaxial layer. The heavily-doped epitaxial layer can have a doping concentration that is greater than a doping concentration of the lightly-doped epitaxial layer. At least a portion of the heavily-doped substrate can be included in a common first terminal of a first Zener diode and a second Zener diode. A first portion of the lightly-doped epitaxial layer and a first portion of the heavily-doped epitaxial layer can be included in a second terminal of the first Zener diode. A second portion of the lightly-doped epitaxial layer and a second portion of the heavily-doped epitaxial layer can be included in a second terminal of the second Zener diode. The semiconductor device can further include a termination trench that extends through the heavily-doped epitaxial layer; extends through the lightly-doped epitaxial layer; and terminates in the heavily-doped substrate. A first portion of the termination trench can electrically isolate the first portion of the lightly-doped epitaxial layer and the first portion of the heavily-doped epitaxial layer from the second portion of the lightly-doped epitaxial layer and the second portion of the heavily-doped epitaxial layer.

In another general aspect, a semiconductor device can include a heavily-doped substrate of a first conductivity type; a lightly-doped epitaxial layer of a second conductivity type disposed on the heavily-doped substrate, the second conductivity type being opposite the first conductivity type; and a heavily-doped epitaxial layer of the second conductivity type disposed on the lightly-doped epitaxial layer. The heavily-doped epitaxial layer can have a thickness that is greater than a thickness of the lightly-doped epitaxial layer. At least a portion of the heavily-doped substrate being included in a first terminal of a Zener diode. At least a portion of the lightly-doped epitaxial layer and at least a portion of the heavily-doped epitaxial layer being included in a second terminal of the Zener diode. The semiconductor device can further include a termination trench that extends through the heavily-doped epitaxial layer; extends through the lightly-doped epitaxial layer; and terminates in the heavily-doped substrate.

### BRIEF DESCRIPTION OF THE DRAWINGS

FIG. 1 is a diagram schematically illustrating a plan view (e.g., a design layout view) of a semiconductor device including a Zener diode, according to an implementation.

FIG. 2 is a diagram schematically illustrating a plan view (e.g., a design layout view) of a semiconductor device including two Zener diodes, according to an implementation.

FIG. 3 is a diagram schematically illustrating a plan view (e.g., a design layout view) of a semiconductor device including a Zener diode, according to an implementation.

FIG. 4A is a diagram illustrating a cross-sectional view of a semiconductor device including a Zener diode, according to an implementation.

FIGS. 4B and 4C are schematic diagrams corresponding with the semiconductor device of FIG. 4A, according to respective implementations.

FIG. 5A is a diagram illustrating a cross-sectional view of a semiconductor device including two Zener diodes, according to an implementation.

FIGS. 5B and 5C are schematic diagrams corresponding with the semiconductor device of FIG. 5A, according to respective implementations.

FIG. 6A is a diagram illustrating a cross-sectional view of a semiconductor device including a Zener diode, according to an implementation.

FIGS. 6B and 6C are schematic diagrams corresponding with the semiconductor device of FIG. 6A, according to respective implementations.

FIG. 7 is a graph illustrating simulation results for Zener diode implementations during an electrical surge event.

FIG. 8 is a graph illustrating simulation results of breakdown voltage performance for Zener diode implementations.

FIG. 9 is a graph illustrating simulation results of clamping current and clamping voltage for Zener diode implementations.

FIG. 10 is a flow chart illustrating a method for producing a semiconductor device including a Zener diode, according to an implementation.

Like reference symbols in the various drawings indicate like and/or similar elements. Elements shown in the various drawings are shown by way of illustration and may not necessarily be to scale. Further, scales of the various drawings may differ from one to another depending, at least in part, on the particular view being shown.

The reference characters in the various drawings are provided for purposes of illustration and discussion. Reference characters for like elements may not be repeated for similar elements in the same view. Also, reference characters shown in one view for a given element may be omitted for that element in related views. Also, reference characters for a given element that is shown in different views may not necessarily be discussed with respect to each of those views.

### DETAILED DESCRIPTION

In this description, Zener diode implementations are disclosed that can have improved performance characteristics as compared to current Zener diode implementations. For instance, the Zener diode implementations described herein, for a given semiconductor diode area (e.g., a silicon surface area of the diode, a conduction surface area, a p-n junction area, etc.), can have improved peak (surge) current capabilities, lower clamping voltages, lower leakage currents and/or improved thermal dissipation capabilities, as compared to current Zener diode implementations of the given semiconductor diode area.

In the following discussion, and in the corresponding drawings, various semiconductor device implementations of Zener diodes are illustrated and described. Briefly, however, Zener diode implementations, such as those described herein, can be implemented using two epitaxial layers (e.g., a first and a second) that are disposed (stacked) on a semiconductor (silicon, silicon-carbide, Gallium Nitride, etc.) substrate. The substrate can be of a first conductivity type (n-type or p-type), and the two epitaxial layers can be of a second conductivity type (p-type or n-type), where the second conductivity type is opposite the first conductivity type. The substrate and the second epitaxial layer can be heavily-doped, while the first epitaxial (e.g. disposed between the substrate and the second epitaxial layer) can be lightly-doped. In some implementations, the first epitaxial layer can have a thickness that is less than a thickness of the second epitaxial layer. In some implementations, a semiconductor device including such a Zener diode can include a termination trench that defines a perimeter of the diode (e.g., terminates the diode) in an associated semiconductor device (e.g., on a semiconductor die), where the termination trench extends through the two epitaxial layer and into the substrate.

In some implementations, a thickness and/or a doping concentration of the first (e.g., lightly-doped) epitaxial layer can be selected based on a desired breakdown voltage (voltage rating) of the Zener diode. That is, the thickness and/or the doping concentration of the first epitaxial layer can be selected so as to establish a breakdown voltage of the Zener diode without significantly impacting corresponding surge performance characteristics. In some implementations, a thickness and/or a doping concentration of the second (e.g., heavily-doped) epitaxial layer can be selected based a desired clamping voltage and/or surge current carrying capability. That is, the thickness and/or the doping concentration of the can epitaxial layer can be selected so as to establish electrical surge performance characteristics of the Zener diode without significantly impacting a corresponding breakdown voltage. Accordingly, using the approaches described herein, a breakdown voltage of a Zener diode can be primarily established (substantially independently of a thickness and doping concentration of the second epitaxial layer) by the first (lightly-doped) epitaxial layer, while the electrical surge performed can be primarily established (substantially independently of a thickness and doping concentration of the first epitaxial layer) by the second (heavily-doped) epitaxial layer.

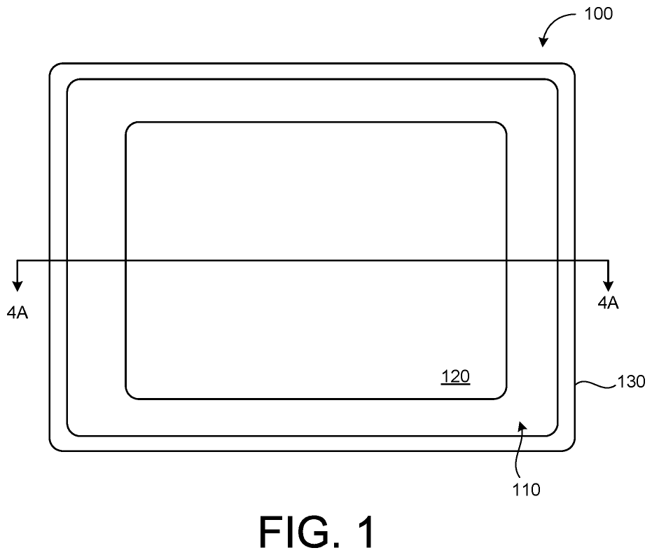

FIG. 1 is a diagram schematically illustrating a plan view (e.g., a design layout view) of a semiconductor device 100 including a Zener diode 110, according to an implementation. In FIG. 1, the Zener diode (diode) 110 is schematically illustrated in a top-down view, as it may be implemented in a semiconductor die. In some implementations, the semiconductor device 100 can include elements other than those shown in FIG. 1. For instance, the semiconductor device 100 could include other circuit components, such as additional Zener diodes, transistors devices, passive electrical elements (resistors, capacitors, etc.), and so forth. Further, the diode 110 can include elements other than those shown in FIG. 1, and the diode 110 is shown by way of example, and for purposes of illustration.

As illustrated in FIG. 1, the diode 110 includes a contact 120, which can be a metal electrode that is included in (provides electrical connection to) a first terminal of the diode 110. In some implementations, a wire bond (not shown) can be connected to the contact 120 (such as in a semiconductor device package, also not shown). Depending on the polarity of the diode 110 (as is discussed further below), the contact 120 can be an anode contact or a cathode contact of the diode 110. In the diode 110, a contact to a second terminal (e.g., the other of an anode and a cathode) can be included on a bottom side (backside, etc.) of the semiconductor device 100 (such as to a leadframe of a semiconductor device package, and is therefore not visible in FIG. 1.

As also shown in FIG. 1, the semiconductor device 100 can include a termination trench 130 that defines a perimeter of (terminates, etc.) the diode 110. In some implementations, the termination trench 130 can have a dielectric material (e.g., silicon-dioxide, silicon nitride, or any other electrically insulating material, etc.) disposed therein, so as to electrically isolate the diode 110 from other portions of a semiconductor die in which the diode 110 is implemented, (e.g., where such isolation can prevent leakage current and/or interference with other circuit elements included in the semiconductor device 100). In some implementations, the termination trench 130 can be a dielectric lined trench that is filled with a polysilicon material.

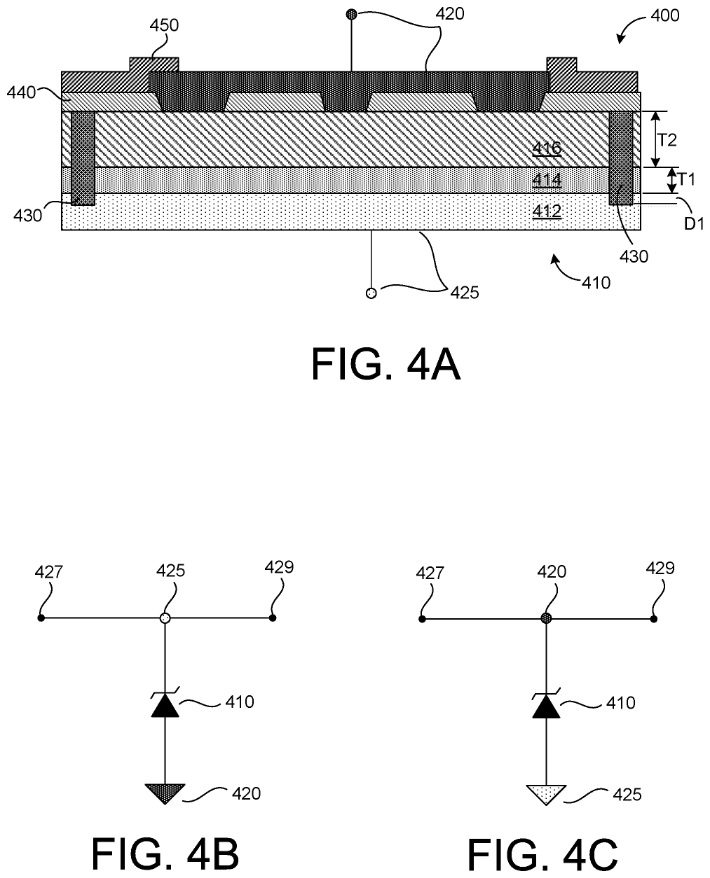

FIG. 1 also includes a section line 4A-4A. The section line 4A-4A corresponds with a cross-sectional view of a Zener diode 410 that is included in a semiconductor device 400, as is illustrated in FIG. 4A and discussed further below. For purposes of reference and comparison to FIG. 4A, in the view of the diode 110 in FIG. 1, an upper (e.g., second) highly-doped epitaxial layer (corresponding with an epitaxial layer 416 in FIG. 4A) of the diode 110 is visible.

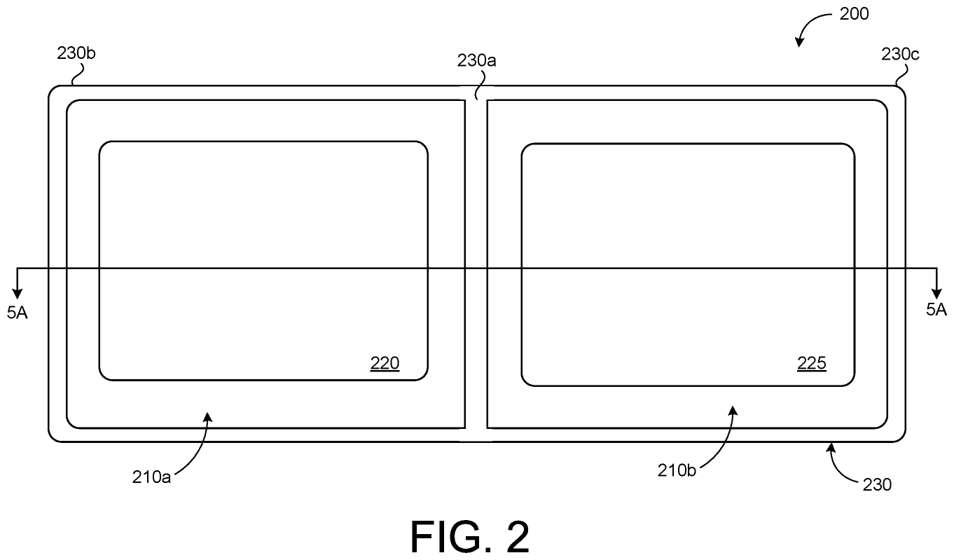

FIG. 2 is a diagram schematically illustrating a plan view (e.g., a design layout view) of a semiconductor device 200 including two Zener diodes 210a and 210b, according to an implementation. In some implementations, the diodes 210a and 210b can be serially connected (e.g., via a common anode or a common cathode included in a substrate of the semiconductor device 200). As with the diode 110 in FIG. 1, the diodes 210a and 210b in FIG. 2 are schematically illustrated in a top-down view, as they may be implemented in a semiconductor die. In some implementations, as with the semiconductor device 100, the semiconductor device 200 can include elements other than those shown in FIG. 2. For instance, the semiconductor device 200 could include other circuit components, such as additional Zener diodes, transistors devices, passive electrical elements (resistors, capacitors, etc.), and so forth. Further, the diodes 210a and 210b can include elements other than those shown in FIG. 2, and the diodes 210a and 210b are shown by way of example, and for purposes of illustration.

As shown in FIG. 2, the diode 210a includes a contact 220, which can be a metal electrode that is included in (provides an electrical connection to) a terminal (e.g., an anode terminal or a cathode terminal) of the diode 210a. The diode 210b in FIG. 2 includes a contact 225, which can be a metal electrode that is included in (provides an electrical connection to) a terminal (e.g., an anode terminal or a cathode terminal) of the diode 210b. In some implementations, wire bonds (not shown) can be connected to the contacts 220 and 225 (such as in a semiconductor device package, also not shown). In some implementations, the contacts 220 and 225 can be flip-chip, or chip-scale package contacts (e.g., can include solder bumps, solder print, etc.). Depending on the polarity of the diodes 210a and 210b (as is discussed further below), the contacts 220 and 225 can be anode contacts or cathode contacts of the respective diodes 210a and 210b.

As also shown in FIG. 2, the semiconductor device 200 can include a termination trench 230 that includes a first portion 230a, a second portion 230b and a third portion 230c. The first portion 230a of the termination trench 230 can isolate (electrically isolate) the diode 210a from the diode 210b. For instance, the first portion 230a of the termination trench 230 can electrically isolate epitaxial layers (e.g., first portions of first and second epitaxial layers) included in the diode 210a from epitaxial layers (e.g., second portions of first and second epitaxial layers) included in the diode 210b.

In the semiconductor device 200, the first portion 230a of the termination trench 230, in combination with the second portion 230b of the termination trench 230, defines a perimeter of (terminates, etc.) the diode 210a. Also in the semiconductor device 200, the first portion 230a of the termination trench 230 in combination with the third portion 230c of the termination trench 230 defines a perimeter of (terminates, etc.) the diode 210b. In some implementations, the termination trench 230 can have a dielectric material (e.g., silicon-dioxide, etc.) disposed therein, so as to electrically isolate the diodes 210a and 210b from each other, and from other portions of a semiconductor die in which the diodes 210a and 210b are implemented, (e.g., where such isolation can prevent leakage current (e.g., between the diodes, between the didoes and other elements, etc.), and/or interference with other circuit elements included in the semiconductor device 200).

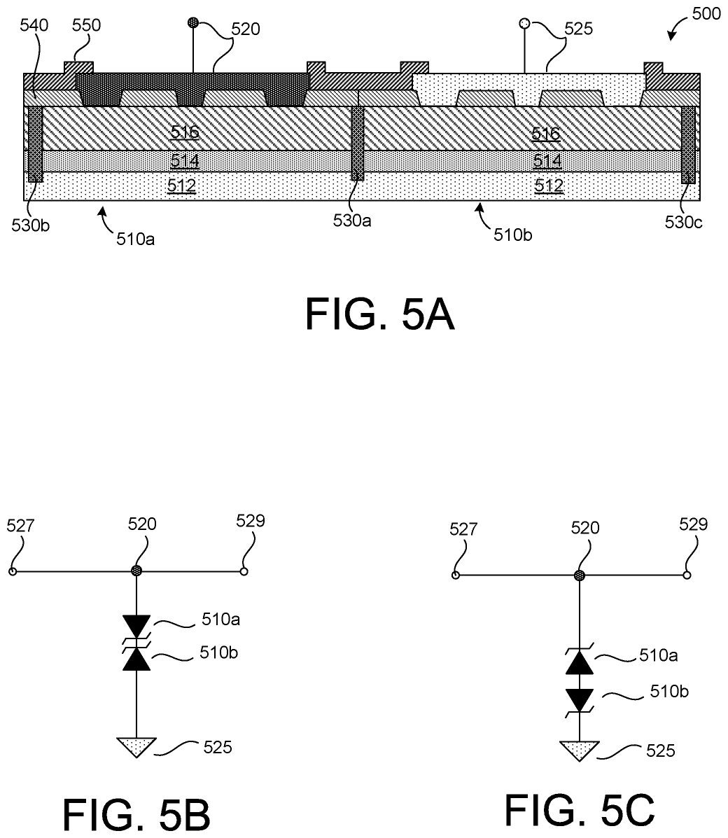

FIG. 2 also includes a section line 5A-5A. The section line 5A-5A corresponds with a cross-sectional view of Zener diodes 510a and 510b that are included in a semiconductor device 500, as is illustrated in FIG. 5A and is discussed further below. For purposes of reference and comparison to FIG. 5A, in the view of the diodes 210a and 210b in FIG. 2, respective portions of an upper (e.g., second) highly-doped epitaxial layer (corresponding with respective portions of an epitaxial layer 516 in FIG. 5A) are visible in FIG. 2.

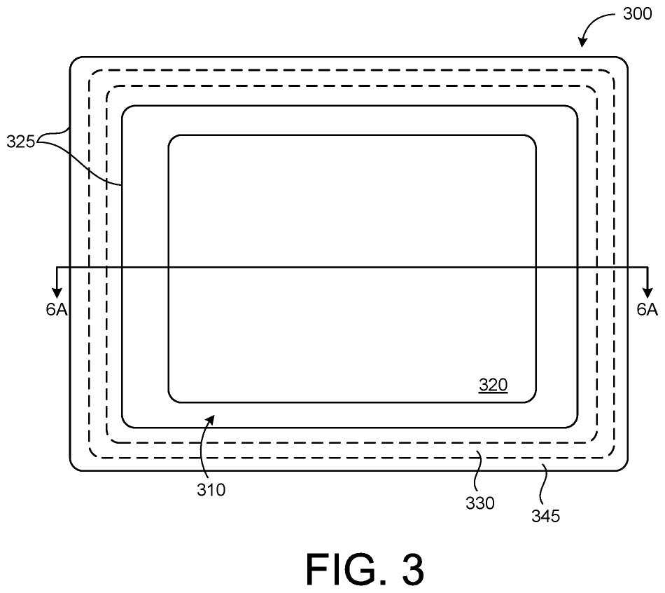

FIG. 3 is a diagram schematically illustrating a plan view (e.g., a design layout view) of a semiconductor device 300 including a Zener diode 310, according to an implementation. In FIG. 3, the diode 310 is schematically illustrated in a top-down view, as it may be implemented in a semiconductor die. In some implementations, as with the semiconductor devices 100 and 200, the semiconductor device 300 can include elements other than those shown in FIG. 3. For instance, the semiconductor device 300 could include other circuit components, such as additional Zener diodes, transistors devices, passive electrical elements (resistors, capacitors, etc.), and so forth. Further, the diode 310 can include elements other than those shown in FIG. 3, and the diode 310 is shown by way of example, and for purposes of illustration.

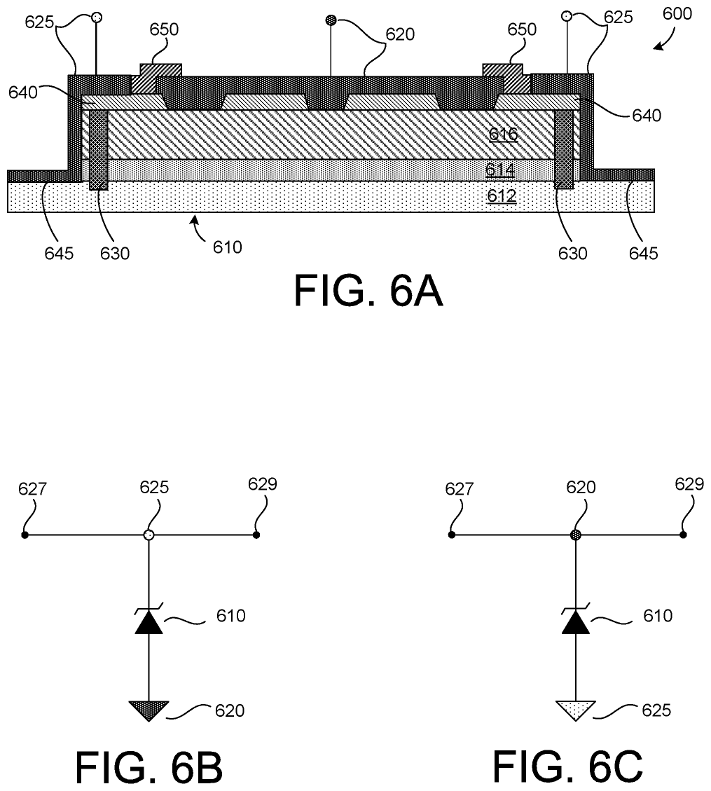

As shown in FIG. 3, the diode 310 includes a contact 320 and a contact 325 (e.g., where inner and outer edges of a metal layer used to form the contact 325 are indicated), which can each be metal electrodes that are respectively included in (provide respective electrical connections to) first and second terminals of the diode 310. In some implementations, the contact 325 can be a contact to a backside (e.g., a substrate) of the diode 310, such as a contact 625 illustrated in FIG. 6A. In some implementations, wire bonds (not shown) can be connected to the contacts 320 and 325 (such as in a semiconductor device package, also not shown). In some implementations, the contacts 320 and 325 can be flip-chip, or chip-scale contacts (e.g., can include solder bumps, solder print, etc.). Depending on the polarity of the diode 310 (as is discussed further below), the contact 320 can be an anode contact or a cathode contact of the diode 310, and the contact 325 can be the other of a cathode contact or an anode contact of the diode 310.

As also shown in FIG. 3, the device 300 can include a termination trench 330 that defines a perimeter of (terminates, etc.) the diode 310, e.g., similar to the termination trench 130 in FIG. 1. In some implementations, the termination trench 330 can have a dielectric material (e.g., silicon-dioxide, etc.) disposed therein, so as to electrically isolate the diode 310 from other portions of a semiconductor die in which the diode 310 is implemented, (e.g., where such isolation can prevent leakage current and/or interference with other circuit elements included in the semiconductor device 300).

As illustrated in FIG. 3, the semiconductor device 300 can also include a backside contact trench 345. As is further illustrated in FIG. 6A, in some implementations, a metal layer used to form the contact 325 can define a low resistance connection from the top side of the device 300 to a backside (e.g., to a heavily doped substrate) of the device 300. That is, in some implementations, a portion (e.g., a first portion) of the metal layer used to form the contact 325 can be disposed in the backside contact trench 345. Further, a second portion of the metal layer use to form the contact 325 can be disposed on a sidewall of the backside contact trench 345 and a third portion of the metal layer use to form the contact 325 can be disposed on an upper surface of the device 300. In the example implementation of FIG. 3, edges of the termination trench 330 and the back side contact trench 345 are shown using dashed lines, which, indicates they are below (e.g., covered by) the metal layer used to form the contact 325.

FIG. 3 also includes a section line 6A-6A. The section line 6A-6A corresponds with a cross-sectional view of a Zener diode 610 that is included in a semiconductor device 600, as is illustrated in FIG. 6A and is discussed further below. For purposes of reference to FIG. 6A, in the view of the diode 310 in FIG. 3, an upper (e.g., second) highly-doped epitaxial layer (corresponding with epitaxial layer 616 in FIG. 6A) of the diode 310 is visible.

FIG. 4A is a cross-sectional view of a semiconductor device 400 including a Zener diode 410, according to an implementation. As noted above, the cross-sectional view of semiconductor device 400, and the diode 410 in FIG. 4A, generally corresponds with a view of an implementation of the semiconductor device 100 and the diode 110 along the section line 4A-4A in FIG. 1. In other words, in some implementations, the diode 410 of FIG. 4A can be used to implement the diode 110 of FIG. 1.

As shown in FIG. 4A, the semiconductor device 400 includes the diode 410, a contact 420 that is included in (is part of) a first terminal of the diode 410 (e.g., an anode or a cathode), a contact 425 (a backside contact) that is included in (is part of) a second terminal of the diode 410 (e.g., the other of the cathode or the anode). In some implementations, the contacts 420 and 425 can include metal electrodes and/or metal layers formed on, and that are electrically coupled with, respective semiconductor layers of the diode 410 (e.g., the substrate 412 and the epitaxial layer 416). As also shown in FIG. 4A, the semiconductor device 400 includes a termination trench 430, which can be similar to the termination trench 130 shown in FIG. 1 (e.g., can surround and/or define a perimeter of the diode 410). In some implementations, the termination trench 430 can have a dielectric (e.g., silicon dioxide, etc.) disposed therein to provide electrical termination and isolation of the diode 410.

In this example implementation, the diode 410 can include at least a portion of a substrate 412, which can be a heavily-doped substrate of a first conductivity type. For example, in some implementations, the substrate 412 can be an n++ type substrate (and included in an anode of the diode 410), or can be a p++ type substrate (and included in a cathode of the diode 410). In some implementations, the substrate 412 can have a doping concentration between 1×10¹⁸ cm⁻³ and 1×10²⁰ cm⁻³.

The diode 410, as shown in FIG. 4A, also includes at least a portion of a first epitaxial layer 414 of a second conductivity type having a thickness of T1, and at least a portion of a second epitaxial layer 416 of the second conductivity type having a thickness of T2. The second conductivity type can be n-type or p-type and, in a given implementation, is of an opposite conductivity type as the substrate 412. In other words, in implementations of the diode 410 where the substrate 412 is n-type, the first epitaxial layer 414 and the second epitaxial layer 416 would be p-type (and included in a cathode of the diode 410), while in implementations of the diode 410 where the substrate 412 is p-type, the first epitaxial layer 414 and the second epitaxial layer 416 would be n-type (and included in an anode of the diode 410). Equivalent circuit diagrams illustrating such implementations are shown in FIGS. 4B and 4C and described below.

A doping concentration of the first epitaxial layer 414 can be less than doping concentration of the second epitaxial layer 416 (e.g., the epitaxial layer 414 can be referred to as being lightly-doped and the epitaxial layer 416 can be referred to as being heavily-doped). In some implementations, a doping concentration of the first epitaxial layer 414 can be in a range of 1×10¹⁵ cm⁻³ to 1×10¹⁹ cm⁻³. In some implementations, a doping concentration of the second epitaxial layer 416 can be in a range of 1×10¹⁸ cm⁻³ to 1×10²⁰ cm⁻³. Use of doped epitaxial layers 414 and 416 can provide performance advantages over prior Zener diode implementations that include diffused, and/or implanted structures (e.g., diffused and/or implanted anode or cathode structures). For instance, leakage of the diode 410 (and other diode structures described herein) can be reduced as compared to prior implementations that include diffused structures, as thermal processing operations used to drive and/or activate dopant impurities of such diffused structures, which can cause distribution (diffusion) of those impurities resulting in increased leakage, may not be performed.

In some implementations, the thickness T1 (of the first epitaxial layer 414) can be less than the thickness T2 (of the second epitaxial layer 416). In some implementations, the thickness T1 can be in a range of 0.5 micrometers (μm) and 10 μm, while the thickness T2 can be in a range of 3 μm and 30 μm. As noted above, the thickness T1 and the doping concentration of the epitaxial layer 414 can be selected, at least in part, to establish a desired breakdown voltage of the diode 410. As also noted above, the thickness T2 and the doping concentration of the epitaxial layer 416 can be selected, at least in part, to establish a desired clamping voltage and/or surge current carrying capability of the diode 410. In some implementations, the thickness of the epitaxial layer 416 (in combination with the thickness of the first epitaxial layer 414) and the resulting depth (e.g., T1+T2) of the PN-junction (between the substrate 410 and the first epitaxial layer 412) of the diode 410 can improve thermal dissipation capabilities of the diode 410 (e.g., due to a resulting volume of the portions of the epitaxial layer 414 and the epitaxial layer 416 included in the diode 410).

As shown in FIG. 4A, the termination trench 430 can be adjacent to, and in contact with (e.g., in direct contact with) the portion of the first epitaxial layer 414 included in the diode 410, and in contact with (e.g., in direct contact with) the portion of the epitaxial layer 416 included in the diode 410. As also shown in FIG. 4A, the termination trench 430 can extend into the substrate 412 to a depth of D1 and be in contact with (e.g., in direct contact with) the substrate 412 and extend around (at least in part) the diode 410. That is, the termination trench 430 can define a perimeter of the diode 410 in the semiconductor device 400. In some implementations, the depth D1 can be in a range of 0.5 μm to 20 μm.

The termination trench 430 (and the termination trenches of other diode implementations described herein) can provide improved performance over prior implementations. For instance, the termination trench 430 can improve electrical isolation of the diode 430, which can reduce leakage of the diode and/or reduce electrical interference of the diode 410, e.g., by preventing lateral current flow from the diode 410 (e.g., to the left and/or to the right of the diode 410 in FIG. 4A), with other devices included in the semiconductor device 400.

In some implementations, the Zener diode implementations described herein, such as the diode 410, can also provide improved performance over prior implementations by reducing leakage current due misfit locations resulting from lattice mismatch between semiconductor layers. For instance, in prior implementation, such dislocations can occur (be present) at a PN-junction interface. As such dislocations can nucleate at or within a depletion region of an associated diode, they can increase a leakage current of the diode. While dislocations can occur in the diode implementations described herein, such dislocations have been empirically observed to occur at the surface of 416 as crosshatchings. In some implementations, these dislocations can originate at the interface between the lightly-doped first epitaxial layer (e.g., the epitaxial layer 414) and the heavily-doped epitaxial layer (e.g., the epitaxial layer 416), and leads to cross-hatching. As such dislocations are not located at the PN-junction (e.g., the interface between the epitaxial layer 414 and the substrate 412) their nucleation is isolated (separated) from the diodes depletion region (e.g., by the epitaxial layer 414) and, therefore, may not contribute (significantly contribute) to a leakage current of an associated diode.

As shown in FIG. 4A, the semiconductor device 400 also includes a dielectric layer 440 and a dielectric layer 450. In this example implementation, the dielectric layer 440 is an interlayer dielectric between the epitaxial layer 416 and a metal layer used to form the contact 420. Also in this example, the dielectric layer 450 is a passivation layer that can be formed to define an opening that can be used for forming a wire bond (or other electrical connection) with the contact 420.

FIGS. 4B and 4C are schematic diagrams corresponding with the semiconductor device of FIG. 4A, according to respective implementations. Accordingly, FIGS. 4B and 4C are described with further reference to FIG. 4A. Like reference numbers in FIGS. 4B and 4C, as those in FIG. 4A, are used to indicate like elements.

In the implementation shown in FIG. 4B, the contact 420 is an anode contact for the diode 410 and the contact 425 is a cathode contact for the diode 410. Accordingly, in this implementation, the substrate 412 of the diode 410 can be n-type (n++), while the epitaxial layers 414 and 416 can be p-type (p- and p++, respectively). As shown in FIG. 4B, the contact 425 can be electrically coupled with a terminal 427 and a terminal 429. In some implementations, the terminal 427 can be coupled with a device (e.g., a circuit element, etc.) that can produce an electrical surge, while the terminal 429 can be connected with a device (e.g., an integrated circuit, etc.) that is protected from such electrical surges by the diode 410. In some implementations, the terminals 427 and 429 (and their respective connections) can be reversed. In some implementations, the diode 410 can protect circuit elements connected to both terminals 427 and 429 from electrical surges.

In the implementation shown in FIG. 4C, the contact 420 is a cathode contact for the diode 410 and the contact 425 is an anode contact for the diode 410. That is, in the implementation of FIG. 4C, the polarity of the diode 410 is reversed as compared to the implementation in FIG. 4B. Accordingly, in this implementation, the substrate 412 of the diode 410 can be p-type (p++), while the epitaxial layer 414 and 416 can be n-type (n- and n++, respectively). As with the contact 425 in the implementation shown in FIG. 4B, in the implementation shown in FIG. 4C, the contact 420 in FIG. 4B can be electrically coupled (e.g., electrically equivalent, directly coupled, etc.) with the terminal 427 and the terminal 429. In some implementations, the terminal 427 can likewise be coupled with a device (e.g., a circuit element, etc.) that can produce an electrical surge, while the terminal 429 can likewise be connected with a device (e.g., an integrated circuit, etc.) that is protected from such electrical surges. In some implementations, the terminals 427 and 429 in FIG. 4C (and their respective connections), as in FIG. 4B can be reversed. In some implementations, the diode 410 can protect circuit elements connected to both terminals 427 and 429 from electrical surges.

FIG. 5A is a cross-sectional view of a semiconductor device 500 including two Zener diodes 510a and 510b, according to an implementation. In some implementations, the diodes 510a and 510b can include similar aspects as the diode 410, and achieve similar benefits, such as the performance improvements described herein. Such aspects include thicknesses of epitaxial layers, conductivity types, depth of a termination trench, doping concentrations of a substrate and epitaxial layers, arrangement of cathode and anode terminals, arrangement and structure of the termination trench (e.g., with respect to the diodes 510a and 510b), metal layers used to form contacts to the diodes 510a and 510b, etc. Accordingly, for purposes of brevity, such details may not be described again here with respect to FIG. 5A (or FIGS. 5B and 5C).

While the diode 410 can protect against both positive and negative surges, it may not be suitable for use in circuits where signals of opposite polarities are used, as the diode 410 can only block voltage in one direction (e.g., during normal operation of the device 400, not during surge events). In comparison, the serially connected diodes 510a and 510b can protect against both positive and negative surges, and also can be used in circuit where signals of both polarities are used, the serially connected diodes of the device 500 can block voltages in both the direction during normal operation of the device.

As noted above, the cross-sectional view of the semiconductor device 500, and the diodes 510a and 510b in FIG. 5A, generally corresponds with a view of an implementation of the semiconductor device 200, and the diodes 210a and 210b, along the section line 5A-5A in FIG. 2. In other words, in some implementations, the diodes 510a and 510b of FIG. 5A can be used to implement the diodes 210a and 210b of FIG. 2.

As shown in FIG. 5A, the semiconductor device 500 includes the diode 510a, a contact 520 that is included in (is part of) a first terminal of the diode 510a (e.g., an anode or a cathode), the diode 510b, and a contact 525 that is included in (is part of) a first terminal of the diode 510b (e.g., an anode or a cathode). In FIG. 5A, the diodes 510a and 510b, depending on their polarity, can have a common anode or a common cathode that is included in a substrate 512 (e.g., a heavily-doped substrate).

As also shown in FIG. 5A, the semiconductor device 500 includes a termination trench including a first portion 530a, a second portion 530b and a third portion 530c. The termination trench in FIG. 5A can be similar to the termination trench 230 shown in FIG. 2. That is, the first portion 530a can isolate (electrically isolate) the diode 510a from the diode 510b. The first portion 530a, in combination with the second portion 530b, can define a perimeter of the diode 510a. Also, the first portion 530a, in combination with the third portion 530c, can define a perimeter of the diode 510b. Further, the second portion 530b of the termination trench 530, in conjunction with the third portion 530c of the termination trench 530, can define a perimeter (e.g., a termination perimeter of the dual diode structure (including the diodes 510a and 510b) of the device 500.

In this example implementation, the diodes 510a and 510b can each include a respective portion of the substrate 512 (of a first conductivity type), where the substrate 512 can include (define, etc.), depending on the polarity of the diodes 510a and 510, a common anode or a common cathode of the diodes 510a and 510b. The diodes 510a and 510b, as shown in FIG. 5A, also include respective portions of a first (e.g., lightly-doped) epitaxial layer 514 (of a second conductivity type), and respective portions of a second (e.g., heavily-doped) epitaxial layer 516 (of the second conductivity type). Equivalent circuit diagrams illustrating implementations of different polarities of the diodes 510a and 510b are shown in FIGS. 5B and 5C and described below.

In the example implementation of FIG. 5A, the semiconductor device 500 also includes a dielectric layer 540 and a dielectric layer 550. In this example implementation, the dielectric layer 540 is an interlayer dielectric between the epitaxial layer 516 and a metal layer used to form the contacts 520 and 525. Also in this example, the dielectric layer 550 is a passivation layer that can be formed to define an opening that can be used for forming wire bonds, or other electrical connections (such as solder bumps, etc.) with the contacts 520 and 525.

FIGS. 5B and 5C are schematic diagrams corresponding with the semiconductor device 500 of FIG. 5A, according to respective implementations. Accordingly, FIGS. 5B and 5C are described with further reference to FIG. 5A Like reference numbers in FIGS. 5B and 5C, as those in FIG. 5A, are used to indicate like elements.

In the implementation shown in FIG. 5B, the contact 520 is an anode contact for the diode 510a and the contact 525 is an anode contact for the diode 510b, with the diodes 510a and 510b having a common cathode contact in the substrate 512. Accordingly, in this implementation, the substrate 512 can be n-type (n++), while the epitaxial layers 514 and 516 can be p-type (p- and p++, respectively).

In the implementation shown in FIG. 5C, the contact 520 is a cathode contact for the diode 510a and the contact 525 is a cathode contact for the diode 510b, with the diodes 510a and 510b having a common anode contact in the substrate 512). In other words, the polarity of the didoes 510a and 510b are reversed as compared to the implementation of FIG. 5B. Accordingly, in this implementation (FIG. 5C), the substrate 512 can be p-type (p++), while the epitaxial layers 514 and 516 can be n-type (n- and n++, respectively).

As shown in FIGS. 5B and 5C, the contact 520 can be electrically coupled with a terminal 527 and a terminal 529. In some implementations, the terminal 527 can be coupled with a device (e.g., a circuit element, etc.) that can produce an electrical surge, while the terminal 529 can be connected with a device (e.g., an integrated circuit, etc.) that is protected from such electrical surges (both positive and negative) by the diodes 510a and 510b. In some implementations, the terminals 527 and 529 (and their respective connections) can be reversed. In some implementations, the diodes 510a and 510b can protect circuit elements connected to both terminals 527 and 529 from electrical surges.

FIG. 6A is a cross-sectional view of a semiconductor device 600 including a Zener diode 610, according to an implementation. In some implementations, the diode 610 can include similar aspects as the diodes 410, 510a and 510b, and achieve similar benefits, such as the performance improvements described herein. Such aspects include thicknesses of epitaxial layers, conductivity types, depth of a termination trench, doping concentrations of a substrate and epitaxial layers, arrangement of cathode and anode terminals, arrangement and structure of the termination trench (e.g., with respect to the diode 610), metal layers used to form contacts to the diode 610, etc. Accordingly, for purposes of brevity, such details may not be described again here with respect to FIG. 6A (or FIGS. 6B and 6C). Similar to the diode 410, the diode 610 can protect against negative surges.

As noted above, the cross-sectional view of the semiconductor device 600, and the diode 610 in FIG. 6A, generally corresponds with a view of an implementation of the semiconductor device 300, and the diode 610, along the section line 6A-6A in FIG. 3. In other words, in some implementations, the diode 610 can be used to implement the diode 310.

As shown in FIG. 6A, the semiconductor device 600 includes the diode 610, a contact 620 that is included in (is part of) a first terminal of the diode 610 (e.g., an anode or a cathode), and a contact 625 (contact to a backside, or substrate of the diode 610) that is included in (is part of) a second terminal of the diode 600 (e.g., the other of cathode or an anode).

As also shown in FIG. 6A, the semiconductor device 600 includes a termination trench 630. The termination trench 630 can be similar to the termination trench 330 shown in FIG. 3. That is, the can define a perimeter of the diode 610, as well as electrically isolate the diode 610 from other elements of the semiconductor device 600.

In this example implementation, the diode 610 includes a portion of a (e.g., heavily-doped) substrate 612 (of a first conductivity type). The diode 610, as shown in FIG. 6A, also includes a portion of a first (e.g., lightly-doped) epitaxial layer 614 (of a second conductivity type), and a portion of a second (e.g., heavily-doped) epitaxial layer 616 (of the second conductivity type). Equivalent circuit diagrams illustrating implementations of different polarities of the diode 610 are shown in FIGS. 6B and 6C and described below.

In the example implementation of FIG. 6A, the semiconductor device 600 also includes a dielectric layer 640 and a dielectric layer 650. In this example implementation, the dielectric layer 640 is an interlayer dielectric between the epitaxial layer 616 and a metal layer used to form the contacts 620 and 625. Also in this example, the dielectric layer 650 is a passivation layer that can be formed to define an opening that can be used for forming wire bonds, or other electrical connections (such as solder bumps, etc.) with the contacts 620 and 625. As shown in FIG. 6A, a metal layer used to form the contact 625 can have portions disposed in (or on) a backside contact trench 645 (e.g., on the heavily doped substrate 612), a sidewall of the backside contact trench 645 (e.g., contacting the epitaxial layers 614 and 616), and an upper surface of the device 600.

FIGS. 6B and 6C are schematic diagrams corresponding with the semiconductor device 600 of FIG. 6A, according to respective implementations. Accordingly, FIGS. 6B and 6C are described with further reference to FIG. 6A Like reference numbers in FIGS. 6B and 6C, as those in FIG. 6A, are used to indicate like elements.

In the implementation shown in FIG. 6B, the contact 620 is a cathode contact for the diode 610, while the contact 625 is an anode contact for the diode 610. In FIG. 6C, the contact 620 is an anode contact, while the contact 625 is a cathode contact for the diode 610 (e.g., the polarity of the diode 610 is reversed in FIG. 6C as compared with FIG. 6B). Accordingly, in FIG. 6B, the substrate 612 can be n-type (n++), while the epitaxial layers 614 and 616 can be p-type (p- and p++, respectively). In FIG. 6C, the substrate 612 can be p-type (p++), while the epitaxial layers 614 and 616 can be n-type (n- and n++, respectively).

As shown in FIGS. 6B and 6C, the contacts 625 and 620, respectively, can be electrically coupled with a terminal 627 and a terminal 629. In some implementations, the terminal 627 can be coupled with a device (e.g., a circuit element, etc.) that can produce an electrical surge, while the terminal 629 can be connected with a device (e.g., an integrated circuit, etc.) that is protected from such electrical surges by the diode 610. In some implementations, the terminals 627 and 629 (and their respective connections) can be reversed. In some implementations, the diode 610 can protect circuit elements connected to both terminals 627 and 629 from electrical surges.

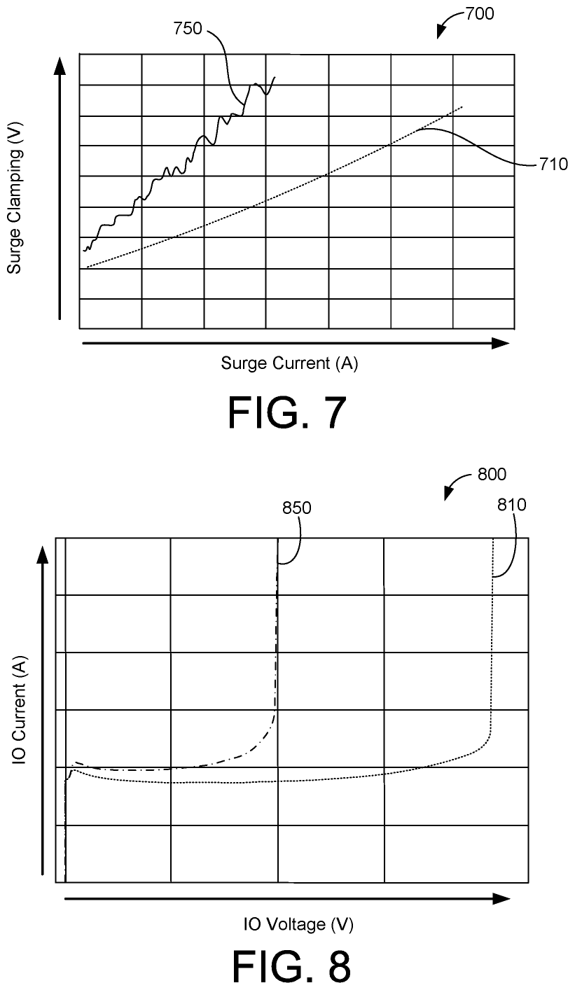

FIG. 7 is a graph 700 illustrating (normalized) simulation results for Zener diode implementations during electrical surge events. The graph 700 illustrates simulation results for surge current and clamping voltage for an implementation of the diode 410 or the diode 610 (shown by the trace 710) as compared to simulation results for a prior diode implementation (shown by the trace 750). The simulation results shown in FIG. 7 are for Zener diode devices with a same working peak reverse voltage rating and a same PN junction area.

As can be seen from the graph 700, for a given clamping current, the trace 710 has a lower clamping voltage than the trace 750. Accordingly, the simulation results shown in FIG. 7 demonstrate that the implementation of the diode 410 or the diode 610 (trace 710) has higher maximum surge current survivability and lower clamping voltage (for a given surge current) than the prior implementation (trace 750). Accordingly, the implementation of the diode 410 would provide better protection against electrical surges than the prior implementation.

FIG. 8 is a graph 800 illustrating (normalized) simulation results of leakage and breakdown voltage performance for Zener diode implementations. The graph 800 illustrates simulation results for an implementation of the diodes 510a and 510b (shown by the trace 810) as compared to simulation results for a prior diode implementation (shown by the trace 850). The simulation results shown in FIG. 8 are for Zener diode devices with similar doping concentrations and diode(PN) junction areas, where termination of the diodes in the prior implementation is shallower than in the implementation of the diodes 510a and 510b.

As can be seen from the graph 800, the implementation of the diodes 510a and 510b (trace 810), at a given voltage (e.g., cathode to anode voltage) has lower leakage current (current prior to breakdown) and, as a result, a higher breakdown voltage. Accordingly, the Zener diode structures described herein, with termination trenches that extend through the two epitaxial layers and extend into the substrate, can provide both improved leakage and breakdown voltage performance over prior implementations.

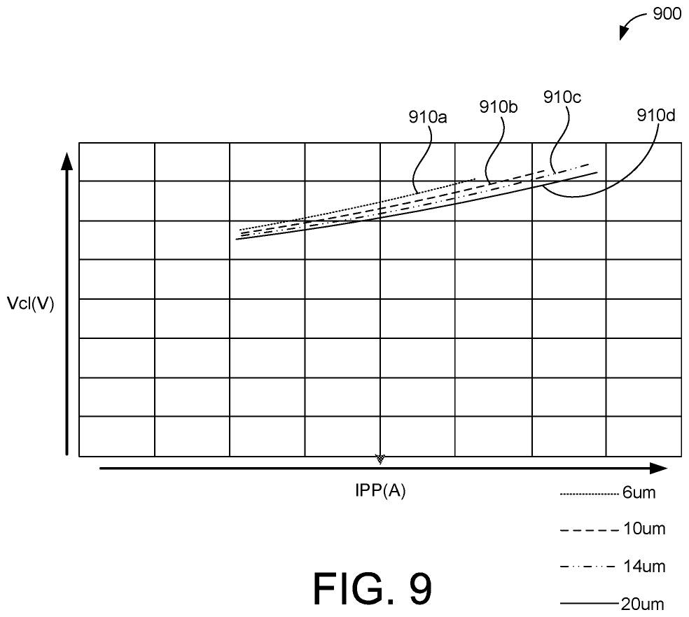

FIG. 9 is a graph 900 illustrating (normalized) simulation results of clamping current and clamping voltage for Zener diode implementations. The simulation results shown in FIG. 9 illustrate clamping voltage and peak operating (surge) current for implementations of the diode 410 (or the diode 610) for various thicknesses (T2, as discussed with respect to FIG. 3) of the heavily-doped epitaxial layer 416. In the simulation results of FIG. 9, a same doping concentration of the epitaxial layer 416 is used (with the lightly-doped epitaxial layer 414 of each device having a same thickness and a same doping concentration). The traces 910a, 910b, 910c and 910d correspond, respectively, with T2 thicknesses of 6 μm, 10 μm, 14 μm and 20 μm. As can be seen from FIG. 9, increasing the thickness T2 of the epitaxial layer 416 can provide improvements in both clamping voltage (e.g., decreases) and peak operating current (e.g., increases). In the graph 900, peak operating currents correspond with the end of each of the traces 910a-910d on the right side of the graph 900. These improvements are due, at least in part, to a reduction in resistance and/or improved thermal dissipation from the increased thickness (T2) of the epitaxial layer 416.

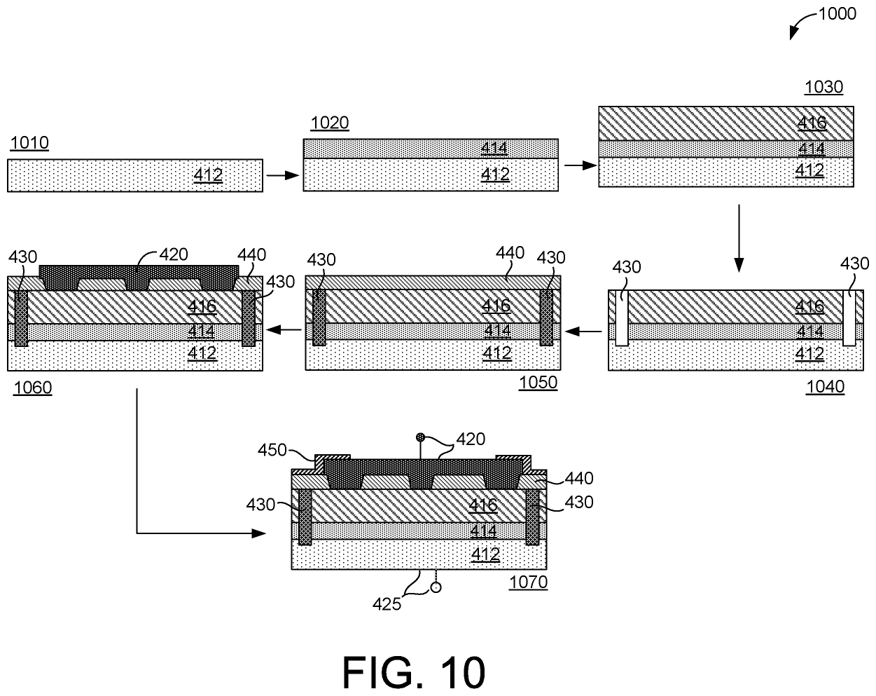

FIG. 10 is a flow chart illustrating a method 1000 for producing a semiconductor device including a Zener diode, according to an implementation. While the method 1000 illustrates a process for producing an implementation of the diode 410 in FIG. 4, it will be appreciated that the processing operations of FIG. 10 can also be used to produce other diode implementations, such as those described herein. For purposes of illustration, the method 1000 will be described with further reference to FIG. 4.

The method 1000 includes, at operation 1010, providing the heavily-doped substrate 412. At operation 1020, the method includes forming the lightly-doped epitaxial layer 414 on (e.g., directly on) the substrate 412. At operation 1030, the method 1000 includes forming the heavily-doped epitaxial layer 416 on (e.g., directly on) the epitaxial layer 414. At operation 1040, the method 1000 includes forming the perimeter trench 430. At operation 1050, the method includes forming (disposing) dielectric material in the perimeter trench 430. In some implementations, the operation 1050 can include performing a thermal oxidation process (e.g., to oxidize the surfaces of the termination trench 130) followed by a dielectric deposition process. As shown in FIG. 10, operation 1050 can also include forming the dielectric layer 440. At operation 1060, the process 1000 includes forming contact openings in the dielectric layer 440 and forming the metal layer for the contact 425. At operation 1070, the method 1000 can include forming the dielectric layer 450 and forming electrical connections (e.g., in a semiconductor device package) for contacts 420 and 425.

The various apparatus and techniques described herein may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to (or laterally neighboring), vertically adjacent to (or vertically neighboring), or horizontally adjacent to (or horizontally neighboring), where neighboring can indicate that intervening element may be disposed between the elements being described as adjacent.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A semiconductor device, comprising:
a heavily-doped substrate of a first conductivity type;
a lightly-doped epitaxial layer of a second conductivity type disposed on the heavily-doped substrate, the second conductivity type being opposite the first conductivity type; and
a heavily-doped epitaxial layer of the second conductivity type disposed on the lightly-doped epitaxial layer, the heavily-doped epitaxial layer having a doping concentration that is greater than a doping concentration of the lightly-doped epitaxial layer,
at least a portion of the heavily-doped substrate being included in a first terminal of a Zener diode, and
at least a portion of the lightly-doped epitaxial layer and at least a portion of the heavily-doped epitaxial layer being included in a second terminal of the Zener diode,
the semiconductor device further comprising a termination trench that:
extends through the heavily-doped epitaxial layer;
extends through the lightly-doped epitaxial layer; and
extends into the heavily-doped substrate.

2. The semiconductor device of claim 1, further comprising at least one of a dielectric material or a polysilicon material disposed in the termination trench.

3. The semiconductor device of claim 1, wherein the termination trench is adjacent to and disposed, at least in part, around the at least a portion of the lightly-doped epitaxial layer and the at least a portion of the heavily-doped epitaxial layer.

4. The semiconductor device of claim 1, wherein the first conductivity type is n-type, the second conductivity type is p-type, the first terminal of the Zener diode is a cathode terminal, and the second terminal of the Zener diode is an anode terminal.

5. The semiconductor device of claim 1, wherein the first conductivity type is p-type, the second conductivity type is n-type, the first terminal of the Zener diode is an anode terminal, and the second terminal of the Zener diode is a cathode terminal.

6. The semiconductor device of claim 1, wherein the heavily-doped epitaxial layer has a thickness that is greater than a thickness of the lightly-doped epitaxial layer.

7. The semiconductor device of claim 6, wherein:
the thickness of the heavily-doped epitaxial layer is in a range between 3 micrometers (μm) and 30 μm; and
the thickness of the lightly-doped epitaxial layer is in a range between 0.5 μm and 10 μm.

8. The semiconductor device of claim 1, wherein:
the doping concentration of the lightly-doped epitaxial layer is in a range of 1×10¹⁵ cm⁻³ to 1×10¹⁹ cm⁻³; and
the doping concentration of the heavily-doped epitaxial layer is in a range of 1×10¹⁸ cm⁻³ to 1×10²⁰ cm⁻³;

9. The semiconductor device of claim 8, wherein the termination trench extends into the heavily-doped substrate to a depth that is between 0.5 μm and 20 μm.

10. A semiconductor device, comprising:
a heavily-doped substrate of a first conductivity type;
a lightly-doped epitaxial layer of a second conductivity type disposed on the heavily-doped substrate, the second conductivity type being opposite the first conductivity type; and
a heavily-doped epitaxial layer of the second conductivity type disposed on the lightly-doped epitaxial layer, the heavily-doped epitaxial layer having a doping concentration that is greater than a doping concentration of the lightly-doped epitaxial layer,
at least a portion of the heavily-doped substrate being included in a common first terminal of a first Zener diode and a second Zener diode, and
a first portion of the lightly-doped epitaxial layer and a first portion of the heavily-doped epitaxial layer being included in a second terminal of the first Zener diode,
a second portion of the lightly-doped epitaxial layer and a second portion of the heavily-doped epitaxial layer being included in a second terminal of the second Zener diode,
the semiconductor device further comprising a termination trench that:
extends through the heavily-doped epitaxial layer;
extends through the lightly-doped epitaxial layer; and
extends into the heavily-doped substrate,
a first portion of the termination trench electrically isolating the first portion of the lightly-doped epitaxial layer and the first portion of the heavily-doped epitaxial layer from the second portion of the lightly-doped epitaxial layer and the second portion of the heavily-doped epitaxial layer.

11. The semiconductor device of claim 10, further comprising a dielectric material disposed in the termination trench.

12. The semiconductor device of claim 10, wherein:
a second portion of the termination trench is adjacent to and disposed, at least in part, around the first portion of the lightly-doped epitaxial layer and the first portion of the heavily-doped epitaxial layer; and
a third portion of the termination trench is adjacent to and disposed, at least in part, around the second portion of the lightly-doped epitaxial layer and the second portion of the heavily-doped epitaxial layer

13. The semiconductor device of claim 10, wherein:
the first conductivity type is n-type;
the second conductivity type is p-type;
the common first terminal of the first Zener diode and the second Zener diode is a common cathode terminal;
the second terminal of the first Zener diode is a first anode terminal; and
the second terminal of the second Zener diode is a second anode terminal.

14. The semiconductor device of claim 10, wherein:
the first conductivity type is p-type;
the second conductivity type is n-type;
the common first terminal of the first Zener diode and the second Zener diode is a common anode terminal;
the second terminal of the first Zener diode is a first cathode terminal; and
the second terminal of the second Zener diode is a second cathode terminal.

15. The semiconductor device of claim 10, wherein the heavily-doped epitaxial layer has a thickness that is greater than a thickness of the lightly-doped epitaxial layer.

16. The semiconductor device of claim 15, wherein:
the thickness of the heavily-doped epitaxial layer is in a range between 5 micrometers (μm) and 20 μm; and
the thickness of the lightly-doped epitaxial layer is in a range between 0.5 μm and 10 μm.

17. The semiconductor device of claim 10, wherein:
the doping concentration of the lightly-doped epitaxial layer is in a range of 1×10¹⁵ cm⁻³ to 1×10¹⁹ cm⁻³; and
the doping concentration of the heavily-doped epitaxial layer is in a range of 1×10¹⁹ cm³ to 1×10²⁰ cm⁻³;

18. The semiconductor device of claim 17, wherein the termination trench extends into the heavily-doped substrate to a depth that is between 0.5 μm and 20 μm.

19. A semiconductor device, comprising:
a heavily-doped substrate of a first conductivity type;
a lightly-doped epitaxial layer of a second conductivity type disposed on the heavily-doped substrate, the second conductivity type being opposite the first conductivity type; and
a heavily-doped epitaxial layer of the second conductivity type disposed on the lightly-doped epitaxial layer, the heavily-doped epitaxial layer having a thickness that is greater than a thickness of the lightly-doped epitaxial layer,
at least a portion of the heavily-doped substrate being included in a first terminal of a Zener diode, and
at least a portion of the lightly-doped epitaxial layer and at least a portion of the heavily-doped epitaxial layer being included in a second terminal of the Zener diode,
the semiconductor device further comprising a termination trench that:
extends through the heavily-doped epitaxial layer;
extends through the lightly-doped epitaxial layer; and
extends into the heavily-doped substrate.

20. The semiconductor device of claim 19, wherein the termination trench is adjacent to and disposed around the at least a portion of the lightly-doped epitaxial layer and the at least a portion of the heavily-doped epitaxial layer.
